(19) United States
(12) Patent Application Publication
(10) Pub. No.: US 2014/0306349 A1
(43) Pub. Date: Oct. 16, 2014

(54) LOW COST INTERPOSER COMPRISING AN OXIDATION LAYER

(71) Applicant: QUALCOMM INCORPORATED, San Diego, CA (US)

(72) Inventors: Shiqun Gu, San Diego, CA (US); Urmi Ray, Ramona, CA (US); Roawen Chen, San Diego, CA (US); Brian Matthew Henderson, Escondido, CA (US); Ratibor Radojcic, San Diego, CA (US); Matthew Nowak, San Diego, CA (US); Nicholas Yu, San Diego, CA (US)

(73) Assignee: QUALCOMM Incorporated, San Diego, CA (US)

(21) Appl. No.: 13/861,086

(22) Filed: Apr. 11, 2013

(51) Int. Cl. H01L 23/498; H01L 21/48

(52) U.S. Cl. CPC H01L 23/49811; H01L 21/486
USPC 257/774; 438/622

(57) ABSTRACT

Some implementations provide an interposer that includes a substrate, a via in the substrate, and an oxidation layer. The via includes a metal material. The oxidation layer is between the via and the substrate. In some implementations, the substrate is a silicon substrate. In some implementations, the oxidation layer is a thermal oxide formed by exposing the substrate to heat. In some implementations, the oxidation layer is configured to provide electrical insulation between the via and the substrate. In some implementations, the interposer also includes an insulation layer. In some implementations, the insulation layer is a polymer layer. In some implementations, the interposer also includes at least one interconnect on the surface of the interposer. The at least one interconnect is positioned on the surface of the interposer such that the oxidation layer is between the interconnect and the substrate.

### BACKGROUND

1. Field

Various features relate to a low cost interposer comprising an oxidation layer.

2. Background

An interposer is a routing component between a first connection and a second connection. For example, an interposer can be located between a die and a ball grid array (BGA). The interposer is configured to spread the pitch between connections and/or redirect a connection to a different connection. FIG. 1 illustrates an example of an interposer in a package. As shown in FIG. 1, the package 100 includes a set of solder balls 102, a package substrate 104, an interposer 106, a first die 108 and a second 110. The set of solder balls 102 is coupled to the package substrate 104. The package substrate includes a first set of vias and interconnects 112 and a second set of vias and interconnects 114.

The interposer 106 is coupled to the package substrate 104. The first die 108 is coupled to the interposer 106. The second die 110 is also coupled to the interposer 106. As shown in FIG. 2, the second die 110 is co-planar (e.g., side-by-side) to the first die 108. The interposer 106 provides an electrical connection (e.g., electrical path) between the first die 108 and the package substrate 104. Similarly, the interposer 106 provides an electrical connection between the second die 110 and the package substrate 104.

Current methods for manufacturing an interposer can be expensive. In the case when the interposer is made of silicon, manufacturing a relatively large interposer is difficult and expensive. As such, there is a need for an improved interposer that is cost efficient, provides excellent electrical properties, and is easy to manufacture relative to current manufacturing processes.

### SUMMARY

Various features, apparatus and methods described herein provide a low cost interposer.

A first example provides an interposer that includes a substrate, a via in the substrate and a first interconnect embedded in a first surface of the interposer, where a first area of the first interconnect is exposed. The via includes a metal material. The interposer also includes an oxidation layer located between the via and the substrate. The oxidation layer is further located between the interconnect and the substrate.

According to an aspect, the substrate is a silicon substrate. In some implementations, the oxidation layer is a thermal oxide formed by exposing the substrate to heat

According to one aspect, the oxidation layer covers the entire surface of the substrate.

According to an aspect, the interposer further includes an insulation layer. The insulation layer is a polymer layer. In some implementations, the oxidation layer covers a second surface portion of the substrate.

According to one aspect, the interposer further includes a second interconnect on a second surface of the interposer. The oxidation layer is further between the second interconnect and the substrate.

According to an aspect, the interposer is configured to be positioned between a printed circuit board (PCB) and at least one die.

According to one aspect, the oxidation layer is configured to provide electrical insulation between the via and the substrate.

According to an aspect, the interposer is incorporated into at least one of a music player, a video player, an entertainment unit, a navigation device, a communications device, a mobile device, a mobile phone, a smartphone, a personal digital assistant, a fixed location terminal, a tablet computer, and/or a laptop computer.

A second example provides an apparatus that includes a substrate, a via in the substrate, and a first interconnect embedded in a first surface of the apparatus, where a first area of the first interconnect is exposed. The via includes a metal material. The apparatus also includes a means for electrical insulation between the via and the substrate. The means for electrical insulation is further between the first interconnect and the substrate.

According to an aspect, the substrate is a silicon substrate. In some implementations, the means for electrical insulation comprises an oxidation layer that is a thermal oxide formed by exposing the substrate to heat.

According to one aspect, the means for electrical insulation includes an oxidation layer that covers the entire surface of the substrate.

According to an aspect, the means for electrical insulation includes an oxidation layer and an insulation layer. In some implementations, the insulation layer is a polymer layer. In some implementations, the oxidation layer covers a second surface portion of the substrate.

According to one aspect, the apparatus further includes a second interconnect on a second surface of the apparatus. The oxidation layer is further between the second interconnect and the substrate.

According to an aspect, the apparatus is an interposer that is configured to be positioned between a printed circuit board (PCB) and at least one die.

According to one aspect, the apparatus is incorporated into at least one of a music player, a video player, an entertainment unit, a navigation device, a communications device, a mobile device, a mobile phone, a smartphone, a personal digital assistant, a fixed location terminal, a tablet computer, and/or a laptop computer.

A third example provides a method for providing an interposer. The method provides a substrate and an oxidation layer on the substrate. The method provides a via in the substrate. The via includes a metal material. The via is provided in the substrate such that the oxidation layer is between the via and the substrate. The method provides a first interconnect in the substrate such that the first interconnect is embedded in a first surface of the interposer and the oxidation layer is between the first interconnect and the substrate. A first area of the first interconnect is exposed.

According to an aspect, the substrate is a silicon substrate. In some implementations, the oxidation layer is a thermal oxide formed by exposing the substrate to heat. In some implementations, the oxidation layer covers the entire surface of the substrate.

According to one aspect, the method further includes providing an insulation layer. In some implementations, the insulation layer is a polymer layer. In some implementations, providing the insulation layer includes providing the insulation layer on the oxidation layer.

According to an aspect, the method further includes providing a second interconnect in the substrate such that the second interconnect is embedded in a second surface of the substrate and the oxidation layer is between the second interconnect and the substrate.

According to one aspect, the interposer is configured to be positioned between a printed circuit board (PCB) and at least one die.

According to an aspect, the oxidation layer is configured to provide electrical insulation between the via and the substrate.

According to one aspect, the interposer is incorporated into at least one of a music player, a video player, an entertainment unit, a navigation device, a communications device, a mobile device, a mobile phone, a smartphone, a personal digital assistant, a fixed location terminal, a tablet computer, and/or a laptop computer.

### DRAWINGS

Various features, nature and advantages may become apparent from the detailed description set forth below when taken in conjunction with the drawings in which like reference characters identify correspondingly throughout.

FIG. 1 illustrates a configuration of an interposer between a die and a printed circuit board (PCB).

FIG. 2 illustrates several interposers that include an oxidation layer.

FIGS. 3A-3B illustrate a sequence for providing/manufacturing an interposer that includes an oxidation layer.

FIGS. 4A-4C illustrate a sequence for providing/manufacturing an interposer that includes an oxidation layer and an insulation layer.

FIG. 5 illustrates various interposers that include an oxidation layer.

FIG. 6 illustrates a wafer that includes an interposer.

FIG. 7 illustrates a method for providing/manufacturing an interposer that includes an oxidation layer.

FIG. 8 illustrates an interposer that includes an oxidation layer.

FIGS. 9A-9C illustrate a sequence for providing/manufacturing an interposer that includes an oxidation layer.

FIG. 10 illustrates an interposer that includes an oxidation layer and several insulative layers.

FIG. 11 illustrates a method for providing/manufacturing an interposer that includes an oxidation layer.

FIG. 12 illustrates various electronic devices that may integrate an integrated circuit and/or PCB described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

### Overview

Some novel features pertain to an interposer that includes a substrate, a via in the substrate, and an oxidation layer. The via includes a metal material. The oxidation layer is between the via and the substrate. In some implementations, the substrate is a silicon substrate. In some implementations, the oxidation layer is a thermal oxide formed by exposing the substrate to oxygen or water vapor at high temperature. In some implementations, the oxidation layer is configured to provide electrical insulation between the via and the substrate. In some implementations, the interposer also includes an insulation layer. The oxidation layer is positioned between the insulation layer and the substrate in some implementations. In some implementations, the insulation layer is a polymer layer. In some implementations, the interposer also includes at least one interconnect on the surface of the interposer. The at least one interconnect is positioned on the surface of the interposer such that the oxidation layer is between the interconnect and the substrate. In some implementations, the interconnect is embedded in the surface of the interposer (e.g., substrate), such that one area of the interconnect is exposed to an environment. In some implementations, the oxidation layer is configured to provide electrical insulation between the interconnect and the substrate.

Exemplary Low Cost Interposer that Includes an Oxidation Layer

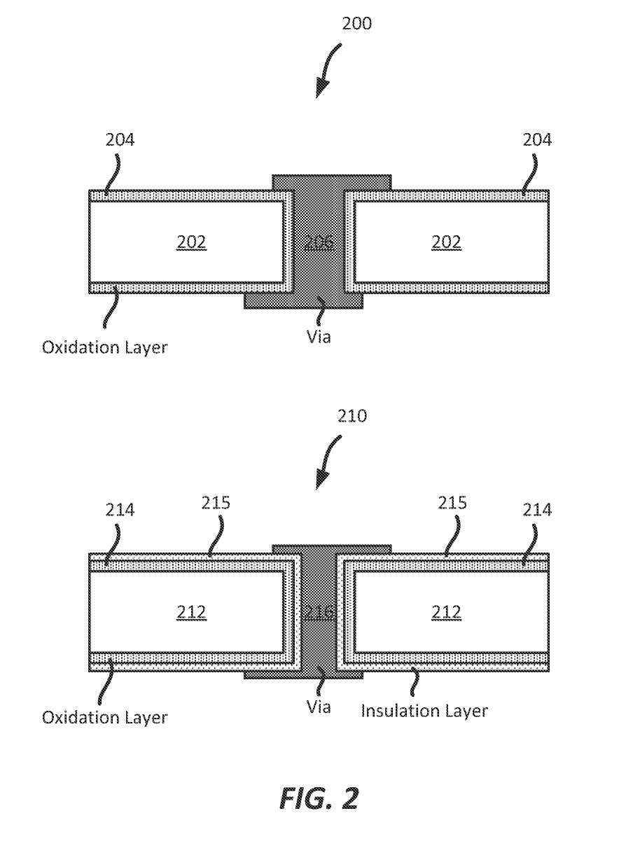

FIG. 2 illustrates a side view of a portion of several interposers that may be used in a package in some implementations. Specifically, FIG. 2 illustrates a portion of a first interposer 200 and a portion of a second interposer 210. As shown in FIG. 2, the first interposer 200 includes a substrate 202, an oxidation layer 204, and a metal layer 206. The substrate 202 may be a silicon substrate in some implementations. In some implementations, a mono crystal silicon or poly-crystalline silicon may be used as substrate for solar cell applications. The oxidation layer 204 is a layer that is formed on an exposed surface of the substrate 202. In some implementations, oxidation occurs when the material (e.g., substrate 202) is subject to air, water and/or other oxidizing environments. In some implementations, the oxidation layer 204 may provide electrical insulation/isolation in the interposer 200 (e.g., prevents electrical signal from traversing through a substrate). For example, the oxidation layer 204 may be configured to provide electrical insulation between the via (e.g., metal layer 206) and the substrate 202.

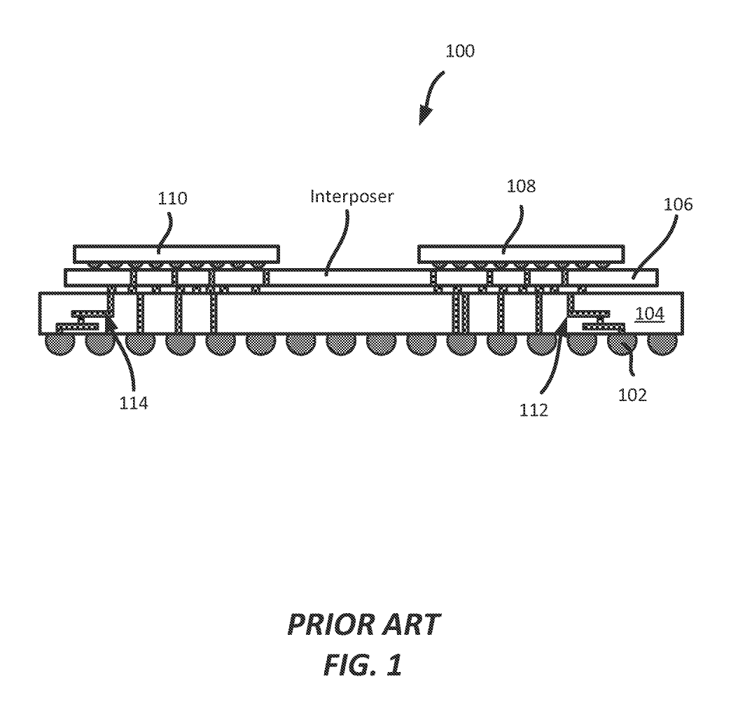

The metal layer 206 defines a via in the interposer 200. A first portion of the via may be coupled to a die (not shown) and a second portion of the via may be coupled to a package substrate (not shown). Thus, in some implementations, the via is defined by the metal layer 206 may provide an electrical path between a package substrate and a die (both not shown). As shown in FIG. 2, the oxidation layer 204 is between the metal layer 206 (e.g., via) and the substrate 202. In some implementations, the oxidation layer 204 prevents an electrical signal traversing the metal layer 206 (e.g., via) from propagating through the substrate 202. In some implementations, the interposer 200 may be configured to be positioned between a printed circuit board (PCB) and at least one die. For example, the novel interposer 200 may replace the interposer 106 of FIG. 1 in some implementations.

As further shown in FIG. 2, the second interposer 210 includes a substrate 212, an oxidation layer 214, an insulation layer 215 and a metal layer 216. The substrate 212 may be a silicon substrate in some implementations. The oxidation layer 214 is a layer that is formed on an exposed surface of the substrate 212. In some implementations, oxidation occurs when the material (e.g., substrate 212) is subject to air, water and/or other oxidizing environments. In some implementations, the oxidation layer 214 may provide electrical insulation/isolation in the interposer 210 (e.g., prevents electrical signal from traversing through substrate). For example, the oxidation layer 214 may be configured to provide electrical insulation between the via (e.g., metal layer 216) and the substrate 212.

The insulation layer 215 is positioned on the oxidation layer 214, such that the oxidation layer 214 is between the insulation layer 215 and the substrate 212. The insulation layer 215 may be a polymer layer. In some implementations, the insulation layer 215 may provide electrical insulation/isolation in the interposer 210 (e.g., prevents electrical signal from traversing through substrate). For example, the insulation layer 215 may be configured to provide electrical insulation between the via (e.g., metal layer 216) and the substrate 212. In some implementations, the combination of the oxidation layer 214 and the insulation layer 215 provides better electrical insulation/isolation in the interposer 210.

The metal layer 206 defines a via in the interposer 210. A first portion of the via may be coupled to a die (not shown) and a second portion of the via may be coupled to a package substrate (not shown). Thus, in some implementations, the via is defined by the metal layer 216 may provide an electrical path between a package substrate and a die (both not shown). As shown in FIG. 2, the oxidation layer 214 is between the metal layer 216 (e.g., via) and the substrate 212. In some implementations, the oxidation layer 214 and the insulation layer 215 prevent an electrical signal traversing the metal layer 216 (e.g., via) from propagating through the substrate 202. In some implementations, the interposer 210 may be configured to be positioned between a printed circuit board (PCB) and at least one die. For example, the novel interposer 210 may replace the interposer 106 of FIG. 1 in some implementations.

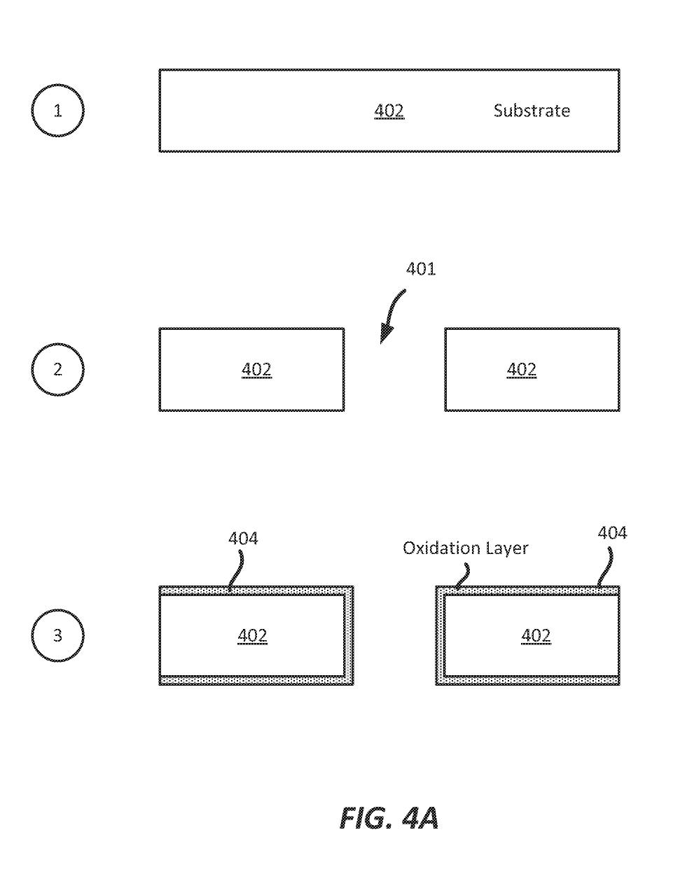

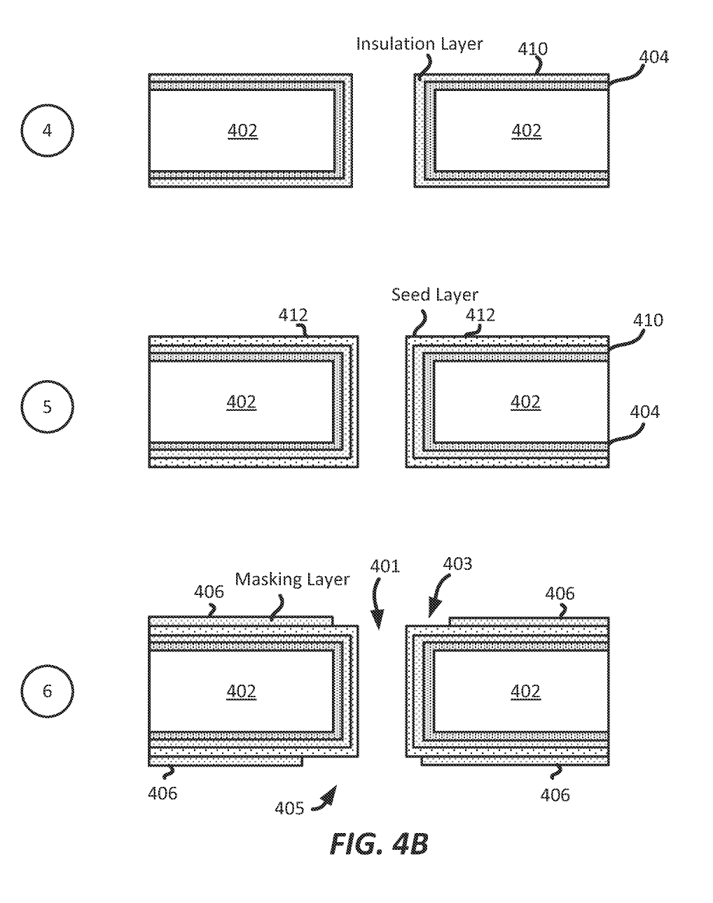

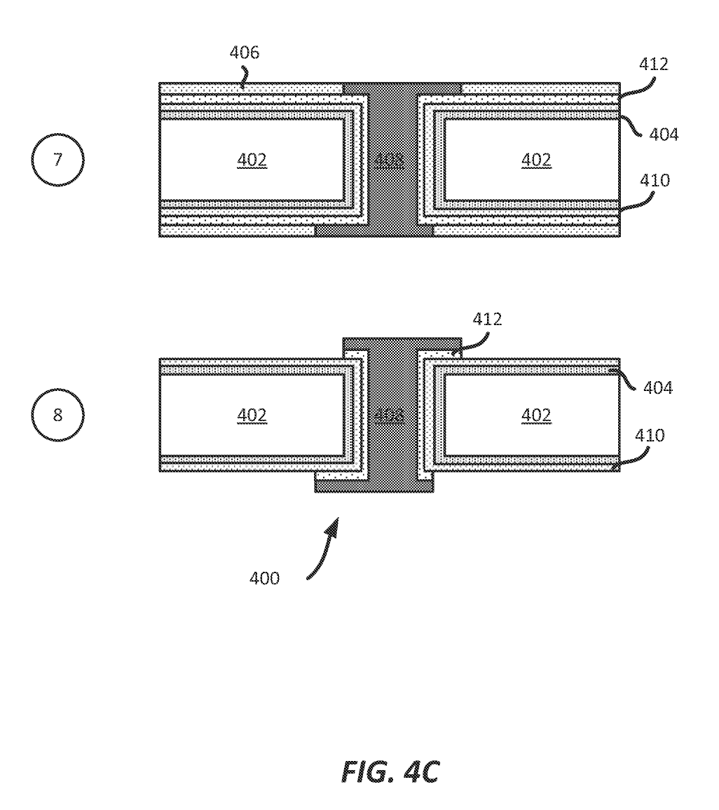

Although only one via is shown in each interposer of FIG. 2, in some implementations, several vias are formed in the interposers 200 and 210. Interposers with multiple vias are further described in FIG. 4. Having described novel interposers that include an oxidation layer, a sequence of a process for providing/manufacturing a interposer that includes an oxidation layer will now be described.

Exemplary Sequence for Providing/Manufacturing an Interposer that Includes an Oxidation Layer

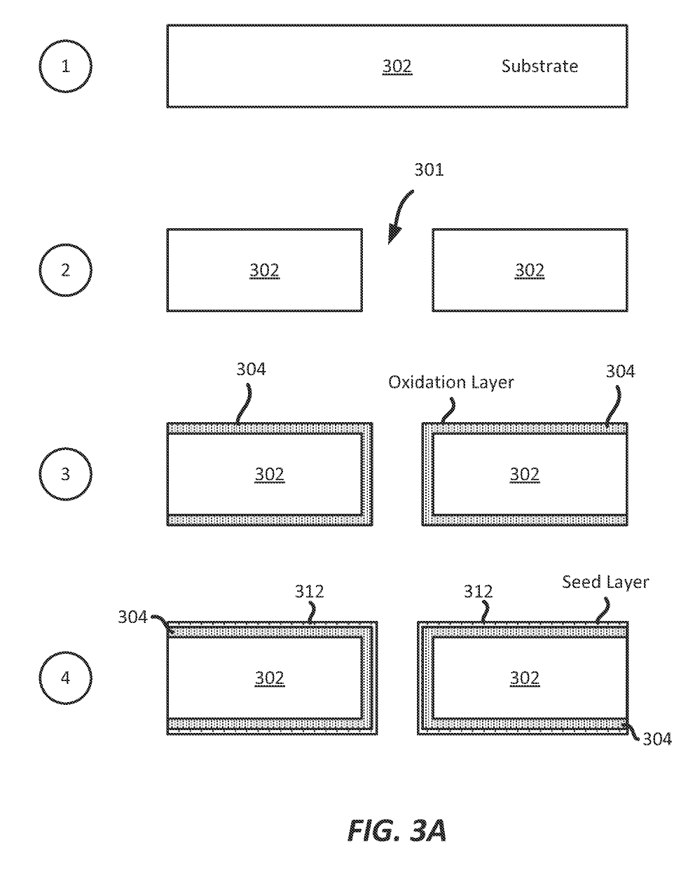

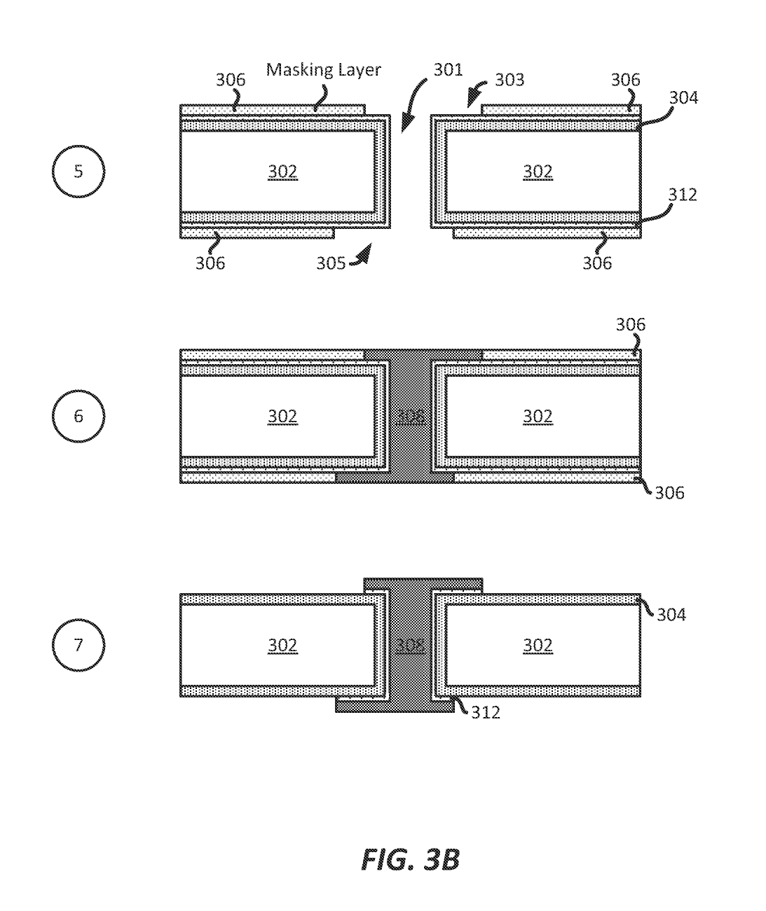

FIGS. 3A-3B and FIGS. 4A-4C illustrate exemplary sequences for providing/manufacturing interposers that includes an oxidation layer. FIGS. 4A-4C is similar to FIGS. 3A-3B, except that the interposer of FIGS. 4A-4C includes an oxidation layer and an insulation layer (e.g., polymer layer).

FIGS. 3A-3B illustrate an exemplary sequence of a process for providing/manufacturing an interposer that includes an oxidation layer. In some implementations, the sequence of FIGS. 3A-3B may be used to provide/manufacture one or more of the interposers of FIG. 2 and/or other interposers described in the present disclosure. As shown in FIG. 3A, at stage 1, a substrate 302 is provided. In some implementations, the substrate 302 is a silicon substrate. The silicon substrate may have a thickness between 30-300 microns (μm) in some implementations. In some implementations, the substrate 302 is a wafer substrate. At stage 2, a cavity 301 is created in the substrate 302. Different implementations may use different techniques and processes for creating the cavity 301. In some implementations, the cavity 301 is created by using a laser to drill the cavity 301 in the substrate 302. In some implementations, the cavity 301 is created by using pattern etching (e.g., lithography, chemical process). Stage 2 illustrates one cavity 301 being created. However, in some implementations, multiple cavities may be created (sequentially and/or concurrently).

At stage 3, an oxidation layer 304 is provided on the substrate 302. In some implementations, an oxidation layer 304 it provided on an exposed surface of the substrate 302. Different implementations may provide the oxidation layer 304 differently. In some implementations, the oxidation layer 304 is provided by exposing the substrate 302 to an oxidizing material (e.g., air, water, O₃, chemical), which forms the oxidation layer 304 (e.g., silicon oxide) on the surface of the substrate 302. In some implementations, the substrate 302 may be exposed to heat under an oxidation environment (e.g., in a furnace) to form the oxidation layer 304 (e.g., thermal oxide). In some implementations, the oxidation layer 304 is provided on a first surface (e.g., top surface) of the substrate 302 during a first exposure of the substrate 302 to heat under an oxidation environment (e.g., in a furnace) and then the oxidation layer 304 is provided on a second surface (e.g., bottom surface) of the substrate 302 during a second exposure of the substrate 302 to heat under an oxidation environment (e.g., in furnace). In some implementations, the oxidation layer 304 is provided on the entire surface of the substrate 302 during a single exposure of the substrate 302 to heat under an oxidation environment (e.g., in a furnace). The oxidation layer 304 may be a liner in some implementations.

At stage 4, a seed layer 312 is provided on the interposer. Specifically, a seed layer 312 is provided on the oxidation layer 304. Different implementations may use different materials for the seed layer 312. In some implementations, the seed layer 312 is a metal layer (e.g., copper layer). For example, the seed layer 312 may be an electrodeless copper seed layer. In some implementations, the seed layer 312 may be provided using physical vapor deposition or chemical vapor deposition.

At stage 5, one or more portions of the masking layer 306 are selectively provided on the seed layer 312. Different implementations may use different methods for selectively providing the masking layer 306. In some implementations, providing the masking layer 306 includes providing a patterned mask layer on one or more surface of the interposer (e.g., top surface, bottom surface). In some implementations, providing the masking layer 306 may include etching the masking layer 306. In some implementations, lithography may be used to selectively etch the masking layer 306. As shown at stage 5, portions of the masking layer 306 are provided (and etched) to form a pattern/cavity (e.g., cavities 303, 305) that will define the outline of one or more vias or portions of one or more vias.

At stage 6, a metal layer 308 is provided in the cavities 301, 303 and 305. The metal layer 308 defines the via in the substrate 302 of the interposer. Different implementations may provide the metal layer 308 differently. In some implementations, the metal layer 308 may be deposited, plated and/or pasted in the cavities 301, 303 and 305.

At stage 7, the masking layer 306 is removed, leaving an interposer 300 with an oxidation layer 304 and a via (e.g., metal layer 308). In some implementations, removing the masking layer 306 includes removing portions of the seed layer 312 (e.g., portions of an electrodeless seed layer). In some implementations, portions of the seed layer 312 between the via (e.g., metal layer 308) and the oxidation layer 304 may remain. In some implementations, the seed layer 312 may be the same material as the metal layer 308. In such instances, the metal layer 308 may be indistinguishable from the seed layer 312. In some implementations, the via may be defined by the metal layer 308 and the seed layer 312.

In some implementations, the interposer 300 may be configured to be positioned between a printed circuit board (PCB) and at least one die. For example, the novel interposer 300 may replace the interposer 106 of FIG. 1 in some implementations.

FIGS. 2 and 3A-3B illustrate a substrate of an interposer covered with an oxidation layer where the interposer includes one via. However, in some implementations, an interposer may include more than one via.

Exemplary Sequences for Providing/Manufacturing an Interposer that Includes an Oxidation Layer and an Insulation Layer

As described above, in some implementations, an interposer may include an oxidation layer and an insulation layer (e.g., polymer layer).

FIGS. 4A-4C illustrate an exemplary sequence of a process for providing/manufacturing an interposer that includes an oxidation layer and an insulation layer. In some implementations, the sequence of FIGS. 4A-4C may be used to provide/manufacture one or more of the interposers of FIG. 2 and/or other interposers described in the present disclosure. As shown in FIG. 4A, at stage 1, a substrate 402 is provided. In some implementations, the substrate 402 is a silicon substrate. The silicon substrate may have a thickness between 30-300 microns (μm) in some implementations. In some implementations, the substrate 402 is a wafer substrate. At stage 2, a cavity 401 is created in the substrate 402. Different implementations may use different techniques and processes for creating the cavity 401. In some implementations, the cavity 401 is created by using a laser to drill the cavity 401 in the substrate 402. In some implementations, the cavity 401 is created by using pattern etching (e.g., lithography, chemical process). Stage 2 illustrates one cavity 401 being created. However, in some implementations, multiple cavities may be created (sequentially and/or concurrently).

At stage 3, an oxidation layer 404 is provided on the substrate 402. In some implementations, an oxidation layer 404 it provided on an exposed surface of the substrate 402. Different implementations may provide the oxidation layer 404 differently. In some implementations, the oxidation layer 404 is provided by exposing the substrate 402 to an oxidizing material (e.g., air, water, chemical), which forms the oxidation layer 404 (e.g., silicon oxide) on the surface of the substrate 402. In some implementations, the substrate 402 may be exposed to heat under an oxidation environment (e.g., in a furnace) to form the oxidation layer 404 (e.g., thermal oxide). In some implementations, the oxidation layer 404 is provided on a first surface (e.g., top surface) of the substrate 402 during a first exposure of the substrate 402 to heat under an oxidation environment (e.g., in a furnace) and then the oxidation layer 404 is provided on a second surface (e.g., bottom surface) of the substrate 402 during a second exposure of the substrate 402 to heat under an oxidation environment (e.g., in furnace). In some implementations, the oxidation layer 404 is provided on the entire surface of the substrate 402 during a single exposure of the substrate 402 to heat under an oxidation environment (e.g., in a furnace). The oxidation layer 404 may be a liner in some implementations.

At stage 4 of FIG. 4B, an insulation layer 410 is provided on the interposer. Specifically, an insulation layer 410 is provided on the oxidation layer 404. Different implementations may use different materials for the insulation layer 410. For example, the insulation layer 410 may be a polymer layer.

At stage 5, a seed layer 412 is provided on the interposer. Specifically, a seed layer 412 is provided on the insulation layer 410. Different implementations may use different materials for the seed layer 412. In some implementations, the seed layer 412 is a metal layer (e.g., copper layer). For example, the seed layer 412 may be an electrodeless copper seed layer.

At stage 6, a masking layer 406 may be provided on the seed layer 412. In some implementations, providing the masking layer 406 includes providing a patterned mask layer on one or more surfaces of the interposer (e.g., top surface, bottom surface). In some implementations, lithography may be used to selectively etch the masking layer 406. As shown at stage 6, portions of the masking layer 406 are etch to form a pattern/cavity (e.g., cavities 403, 405) that will define the outline of one or more vias or portions of one or more vias.

At stage 7 of FIG. 4C, a metal layer 408 is provided in the cavities 401, 403 and 405. The metal layer 408 defines the via in the substrate 402 of the interposer. Different implementations may provide the metal layer 408 differently. In some implementations, the metal layer 408 may be deposited, plated and/or pasted in the cavities 401, 403 and 405.

At stage 8, the masking layer 406 is removed, leaving an interposer 400 with an oxidation layer 404 and a via (e.g., metal layer 408). In some implementations, removing the masking layer 406 includes removing portions of the seed layer 412 (e.g., portions of an electrodeless seed layer). In some implementations, portions of the seed layer 412 between the via (e.g., metal layer 408) and the insulation layer 410 may remain. In some implementations, the seed layer 412 may be the same material as the metal layer 408. In such instances, the metal layer 408 may be indistinguishable from the seed layer 412. In some implementations, the via may be defined by the metal layer 408 and the seed layer 412.

In some implementations, the interposer 400 may be configured to be positioned between a printed circuit board (PCB) and at least one die. For example, the novel interposer 400 may replace the interposer 106 of FIG. 1 in some implementations.

FIGS. 4A-4C illustrate a substrate of an interposer covered with an oxidation layer where the interposer includes one via. However, in some implementations, an interposer may include more than one via.

Exemplary Interposer that Includes an Oxidation Layer and an Insulation Layer

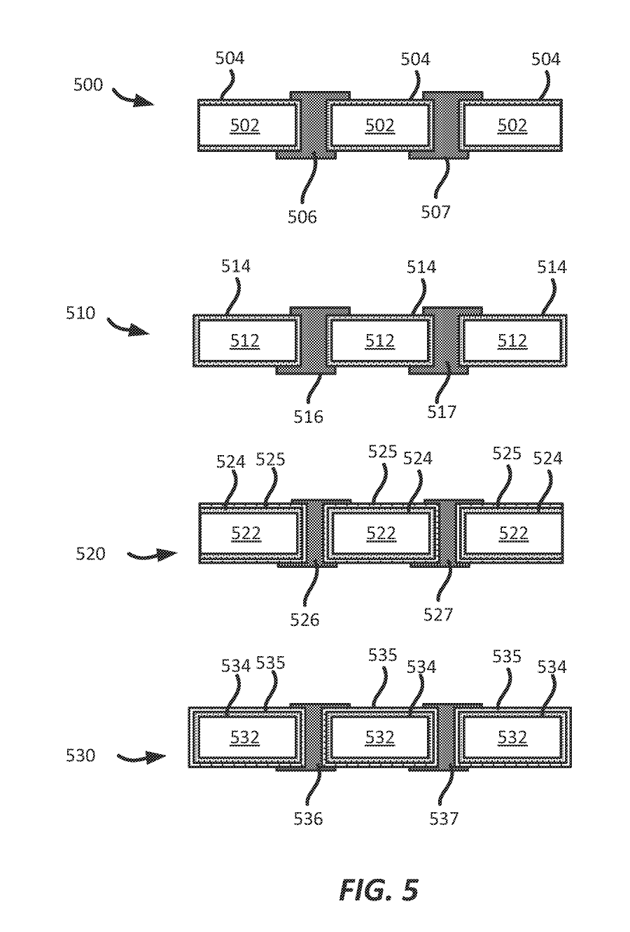

FIG. 5 illustrates various interposers with more than one via. Specifically, FIG. 5 illustrates a first interposer 500, a second interposer 510, a third interposer 520 and a fourth interposer 530.

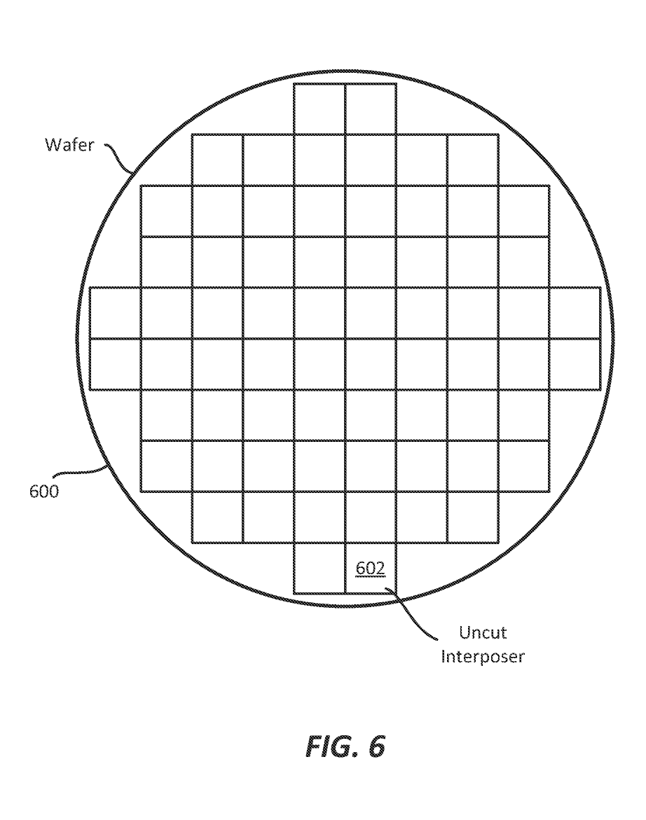

The first interposer 500 includes a substrate 502, an oxidation layer 504, a first via 506 and a second via 507. The substrate 502 may be a silicon substrate in some implementations. The first and second vias 506-507 may be a metal material (e.g., copper). In some implementations, the oxidation layer 504 may be a thermal oxide that is formed by subjecting the surface of the substrate 502 to heat under an oxidation environment (e.g., in a furnace). FIG. 5 also illustrates that the outer side portion (e.g., outer side surface) of the substrate 502 (e.g., outside surface of the interposer 500) is free of the oxidation layer 504. In some implementations, the outer side surface of the interposer 500 may be free of the oxidation layer 504 when the interposer 500 is cut from a wafer, after the oxidation layer 504 is provided on the substrate 502 (e.g., after the oxidation layer is provided on the wafer). Although not shown, a seed layer may be located between the vias (e.g., first via 506 and the second via 507) and the oxidation layer 504. In some implementations, the seed layer may be the same material as the via. As such, the seed layer may be indistinguishable from the via. In some implementations, the seed layer may be part of the via. A wafer that includes interposers will be further described in FIG. 6.

In some implementations, an oxidation layer may also be provided on the outside side surface of an interposer and/or substrate.

The second interposer 510 of FIG. 5 illustrates an example of such an interposer. As shown in FIG. 5, the second interposer 510 includes a substrate 512, an oxidation layer 514, a first via 516 and a second via 517. The substrate 512 may be a silicon substrate in some implementations. The first and second vias 516-517 may be a metal material (e.g., copper). In some implementations, the oxidation layer 514 may be a thermal oxide that is formed by subjecting the surface of the substrate 512 to heat under an oxidation environment (e.g., in a furnace). As described above, the entire surface of the substrate 512 is covered with the oxidation layer 514, including the outer side surface of the substrate 512 (e.g., outer side surface of the interposer 510). In some implementations, the outer side surface of the interposer 510 may include the oxidation layer 514 when the interposer 510 is cut from a wafer, before the oxidation layer 514 is provided on the substrate 512. Although not shown, a seed layer may be located between the vias (e.g., first via 516 and the second via 517) and the oxidation layer 514. In some implementations, the seed layer may be the same material as the via. As such, the seed layer may be indistinguishable from the via. In some implementations, the seed layer may be part of the via.

The third interposer 520 includes a substrate 522, an oxidation layer 524, an insulation layer 525, a first via 526 and a second via 527. The substrate 522 may be a silicon substrate in some implementations. The first and second vias 526-527 may be a metal material (e.g., copper). In some implementations, the oxidation layer 524 may be a thermal oxide that is formed by subjecting the surface of the substrate 522 to heat under an oxidation environment (e.g., in a furnace). FIG. 5 also illustrates that the outer side portion (e.g., outer side surface) of the substrate 522 (e.g., outside surface of the interposer 520) is free of the oxidation layer 524. In some implementations, the outer side surface of the interposer 520 may be free of the oxidation layer 524 when the interposer 520 is cut from a wafer, after the oxidation layer 524 is provided on the substrate 522 (e.g., after the oxidation layer is provided on the wafer). The insulation layer 525 is provided on the oxidation layer 524. In some implementations, the insulation layer 525 is a polymer layer. Although not shown, a seed layer may be located between the vias (e.g., first via 526 and the second via 527) and the insulation layer 525. In some implementations, the seed layer may be the same material as the via. As such, the seed layer may be indistinguishable from the via. In some implementations, the seed layer may be part of the via.

The fourth interposer 530 includes a substrate 532, an oxidation layer 534, an insulation layer 535, a first via 536 and a second via 537. The substrate 532 may be a silicon substrate in some implementations. The first and second vias 536-537 may be a metal material (e.g., copper). In some implementations, the oxidation layer 534 may be a thermal oxide that is formed by subjecting the surface of the substrate 532 to heat under an oxidation environment (e.g., in a furnace). As described above, the entire surface of the substrate 532 is covered with the oxidation layer 534, including the outer side surface of the substrate 532 (e.g., outer side surface of the interposer 530). In some implementations, the outer side surface of the interposer 530 may include the oxidation layer 534 when the interposer 530 is cut from a wafer, before the oxidation layer 534 is provided on the substrate 532. The insulation layer 535 is provided on the oxidation layer 534. In some implementations, the insulation layer 535 is a polymer layer. Although not shown, a seed layer may be located between the vias (e.g., first via 536 and the second via 537) and the oxidation layer 534. In some implementations, the seed layer may be the same material as the via. As such, the seed layer may be indistinguishable from the via. In some implementations, the seed layer may be part of the via.

In some implementations, the substrate that is used to provide/manufacture the interposer (e.g., interposers 200, 300, 400, 500, 510, 520 and 530) is a substrate from a wafer. FIG. 6 illustrates an example of a wafer 600 that may be used to provide an interposer. As shown in FIG. 6, the wafer 600 includes multiple uncut interposers 602. These interposers 602 may be one or more of the novel interposers previously described above (e.g., interposers 200, 300, 400, 500, 510, 520 and 530) or any of the novel interposers described in the present application. Different implementations may cut the interposers from the wafer during different stages of the manufacturing of the interposers. In some implementations, the interposers (e.g., interposer 602) are cut after the oxidation layer has been provided on the wafer/substrate and the vias have been defined. For example, in some implementations, the interposers are cut after stage 7 of FIG. 3B or stage 8 of FIG. 4C. The shape of the wafer could be circular or rectangular.

In view of the fact that interposers may be cut from the wafer 600 during different stages of a manufacturing process, the uncut interposer 602 shown in FIG. 6 may represent a completed/finished interposer (e.g., interposers 200, 300, 400, 500, 510, 520 and 530) or the uncut interposer 602 may represent an interposer that is in the process of being manufactured.

Having described a sequence for providing a novel interposer that includes an oxidation layer, a method for providing/manufacturing an interposer that includes an oxidation layer will now be described.

Exemplary Method for Providing/Manufacturing an Interposer that Includes an Oxidation Layer

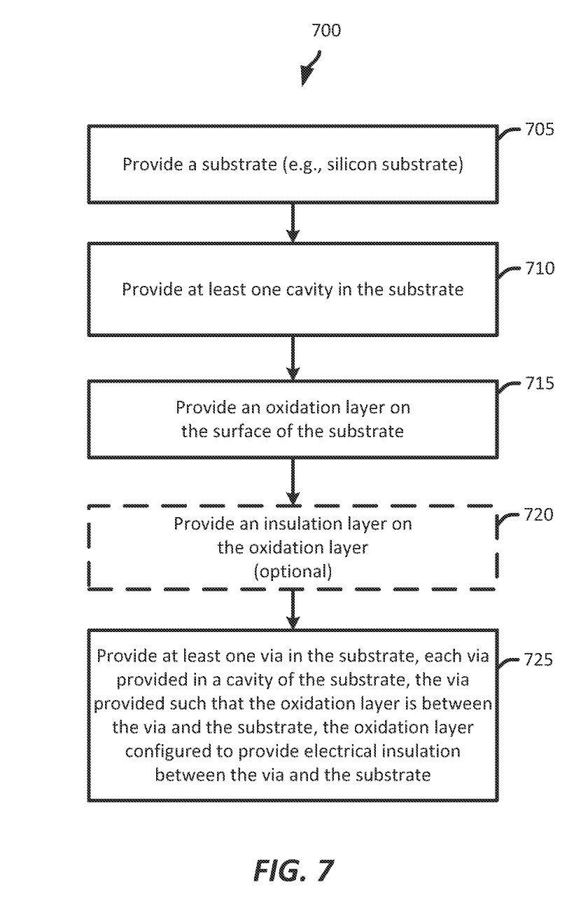

FIG. 7 illustrates an exemplary method for providing/manufacturing an interposer that includes an oxidation layer. In some implementations, the method of FIG. 7 may be used to provide/manufacture the interposers of FIGS. 2, 3B, 4C and/or 5, as well as other interposers described in the present disclosure. As shown in FIG. 7, the method provides (at 705) a substrate. In some implementations, the substrate is a silicon substrate. The silicon substrate may have a thickness between 30-300 microns (μm) in some implementations. The substrate may be a singular piece of substrate that is cut from a wafer (e.g., wafer 500) in some implementations. In some implementations, providing (at 705) the substrate may include providing a wafer (e.g., wafer 500).

The method provides (at 710) at least one cavity in the substrate and/or wafer. Different implementations may provide the at least one cavity by using different techniques and processes. In some implementations, providing (at 710) the at least one cavity includes using a laser to drill the at least one cavity (e.g., cavity 301) in the substrate (e.g., substrate 302). In some implementations, providing (at 710) the at least one cavity includes pattern etching (e.g., lithography, chemical process, dry etching, wet etching). In the instance that multiple cavities are provides in the substrate, the cavities may be provided/created sequentially or concurrently in the substrate and/or wafer.

The method then provides (at 715) an oxidation layer on the substrate and/or wafer. In some implementations, providing (at 715) the oxidation layer includes providing an oxidation layer on an exposed surface of the substrate. Different implementations may provide the oxidation layer differently. In some implementations, the oxidation layer is provided by exposing the substrate to an oxidizing material (e.g., air, water, chemical), which forms the oxidation layer (e.g., silicon oxide) on the surface of the substrate and/or wafer. In some implementations, the substrate may be exposed to heat under an oxidation environment (e.g., in a furnace) to form the oxidation layer (e.g., thermal oxide). In some implementations, the oxidation layer is provided on a first surface (e.g., top surface) of the substrate during a first exposure of the substrate to heat under an oxidation environment (e.g., in a furnace) and then the oxidation layer is provided on a second surface (e.g., bottom surface) of the substrate during a second exposure of the substrate to heat under an oxidation environment (e.g., in furnace). In some implementations, the oxidation layer is provided on the entire surface of the substrate during a single exposure of the substrate to heat under an oxidation environment (e.g., in a furnace). The oxidation layer may be a liner in some implementations.

The method then optionally provides (at 720) an insulation layer. In some implementations, providing (at 720) the insulation layer includes providing an insulation layer on the oxidation layer. In some implementations, the insulation layer is a polymer layer.

The method then provides (at 725) at least one via in the substrate. In some implementations, providing (at 725) the at least one via includes filling one or more the cavities with a metal material (e.g., copper) to define one or more vias in the substrate. The one or more vias is provide on the substrate such that the oxidation layer is between the via and the substrate. The oxidation layer is configured to provide electrical insulation between the via and the substrate. Different implementations may provide the one or more vias differently.

In some implementations, providing (at 725) one or more vias includes providing a masking layer (e.g., masking layer 306) on the interposer. Specifically, a masking layer (e.g., patterned mask layer) is provided on the oxidation layer that is on the substrate. Different implementations may use different materials and methods for providing for the masking layer.

In some implementations, providing (at 725) one or more vias also includes selectively etching one or more portions of the masking layer to provide a patterned mask layer. Different implementations may use different methods for selectively etch the masking layer. In some implementations, lithography may be used to selectively etch the masking layer, which forms patterns/cavities (e.g., cavities 303, 305) that define the outline of one or more vias or portions of one or more vias.

In some implementations, providing (at 725) one or more vias also includes providing a material (e.g., metal material) in the patterns/cavities. The material defines the one or more vias in the substrate of the interposer. Different implementations may provide the material differently. In some implementations, the material (e.g., metal layer) may be deposited, plated and/or pasted in the patterns/cavities.

In some implementations, providing (at 725) one or more vias also includes removing the masking layer (e.g., patterned mask layer), leaving an interposer with an oxidation layer and one or more vias. In some implementations, removing the masking layer may include removing a portion of an electrodeless seed layer.

In some implementations, when the substrate that is provided (at 705) is a wafer (e.g., wafer 600), the method may cut (e.g., after 725) the wafer into singular pieces of interposers (e.g., interposer 602) using known cutting/dicing techniques and processes.

Exemplary Interposer with Oxidation Layer, Via and Interconnect

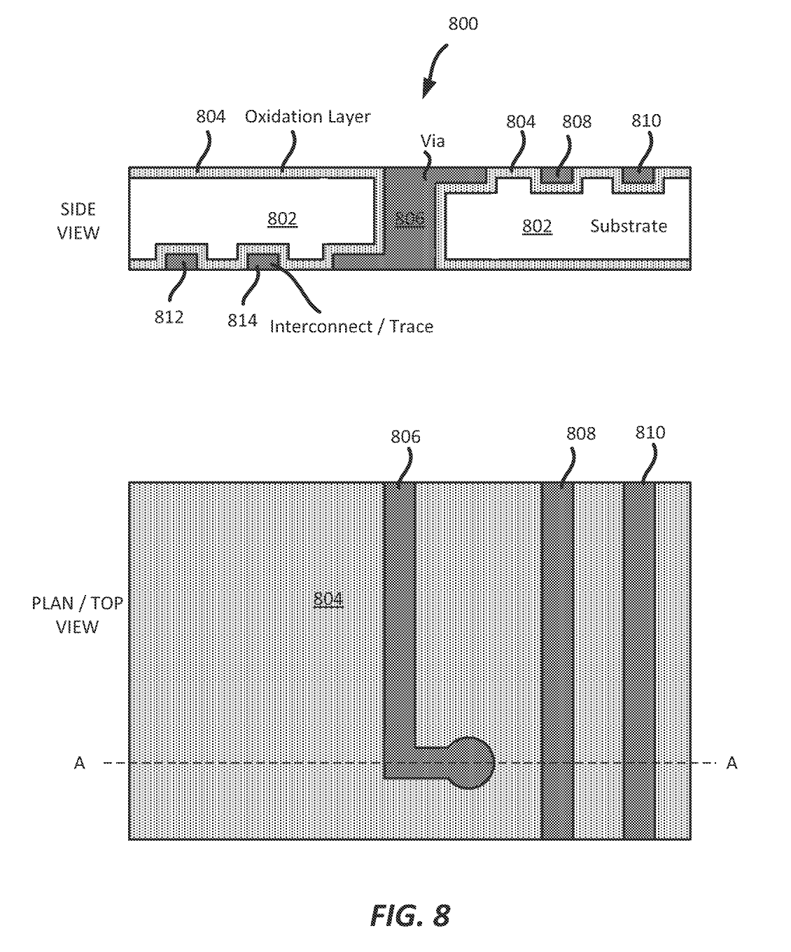

In addition to vias, an interposer may also include interconnects/traces. FIG. 8 illustrates an exemplary interposer that includes a via and interconnects. Specifically, FIG. 8 illustrates a side view and a plan view (e.g., top view) of a portion of an interposer 800. The side view of FIG. 8 is a view of the interposer 800 along the AA cross section of the plan view of FIG. 8.

The interposer 800 includes a substrate 802, an oxidation layer 804, a first metal layer 806, a first interconnect 808, a second interconnect 810, a third interconnect 812 and a fourth interconnect 814. The substrate 802 may be a silicon substrate in some implementations. The oxidation layer 804 is a layer that is formed on an exposed surface of the substrate 802. In some implementations, the oxidation layer 804 may provide electrical insulation/isolation in the interposer 800 (e.g., prevents electrical signal from traversing through substrate). The first metal layer 806 defines a via in the interposer 800.

The first interconnect 808 is a metal layer on a first surface (e.g., top surface) of the interposer 800. The second interconnect 810 is a metal layer on the first surface (e.g., top surface) of the interposer 800. As shown in FIG. 8, the first interconnect 808 and the second interconnect 810 are embedded in the interposer 800. Specifically, one surface (e.g., top surface) of the interconnect is exposed (e.g., to an environment), while the sides of the interconnect are covered by the oxidation layer 804. In some implementations, the first interconnect 808 and the second interconnect 810 (e.g., embedded interconnects/traces) are embedded in the interposer 800 such that the first and second interconnects 808 and 810 are flush (e.g., aligned) with the surface of the interposer 800 and/or below the surface of the interposer 800. Different implementations may embed interconnects/traces differently in an interposer. That is, different implementations may embed interconnects/traces at different depths of the interposer (e.g., different depths of the substrate and/or oxidation layer). In some implementations, an embedded interconnect/trace (e.g., interconnect/trace embedded in an interposer) may be an interconnect/trace that is embedded in the substrate (e.g., silicon) and/or oxidation layer of the interposer. In some implementations, interconnects/traces may be completely embedded in the interposer. In some implementations, interconnects/traces may be partially embedded in the interposer (e.g., only portion of the interconnects/traces area embedded, leaving a first area and portions of side areas exposed). Interconnects/traces may also be substantially embedded or a majority of the thickness (e.g., height) of the interconnects/traces may be embedded. In some implementations, the spacing between the interconnects may be 30 microns (μm) or less. In some implementations, a spacing between interconnects is the distance between the edges of two neighboring interconnects. In some implementations, the spacing between a via and a neighboring interconnect may be 30 microns (μm) or less.

The third interconnect 812 is a metal layer on a second surface (e.g., bottom surface) of the interposer 800. The fourth interconnect 814 is a metal layer on the second surface (e.g., bottom surface) of the interposer 800. As shown in FIG. 8, the third interconnect 812 and the fourth interconnect 814 are embedded in the interposer 800. Specifically, one surface (e.g., bottom surface) of the interconnect is exposed (e.g., to an environment), while the sides of the interconnect are covered by the oxidation layer 804. In some implementations, the third interconnect 812 and the fourth interconnect 814 are embedded in the interposer 800 such that the third and fourth interconnects 812 and 814 are flush with the surface of the interposer 800 and/or below the surface of the interposer 800.

One advantage of embedding interconnects (e.g., interconnects 808, 810, 812, 814) in the interposer is that it provides a thinner interposer compared to interposers that have traces (e.g., raised traces, surface traces) that are provided on top of the surface of the interposer (e.g., completely above/on top of surface of substrate).

As shown in FIG. 8, the oxidation layer 804 is between the metal layers 806-810 and the substrate 802. As mentioned above, the oxidation layer 804 provides an insulation layer that prevents electrical signals from traversing through the substrate 802. For example, the oxidation layer 804 may be configured to provide electrical insulation between the via 806 and the substrate 802. In some implementations, the oxidation layer 804 may be configured to provide electrical insulation between the interconnect/trace (e.g., interconnects 808, 810, 812, 814) and the substrate 802.

Having described a novel interposer that includes an oxidation layer, a sequence of a process for providing/manufacturing an interposer that includes an oxidation layer will now be described.

Exemplary Sequence for Providing/Manufacturing an Interposer that Includes an Oxidation Layer

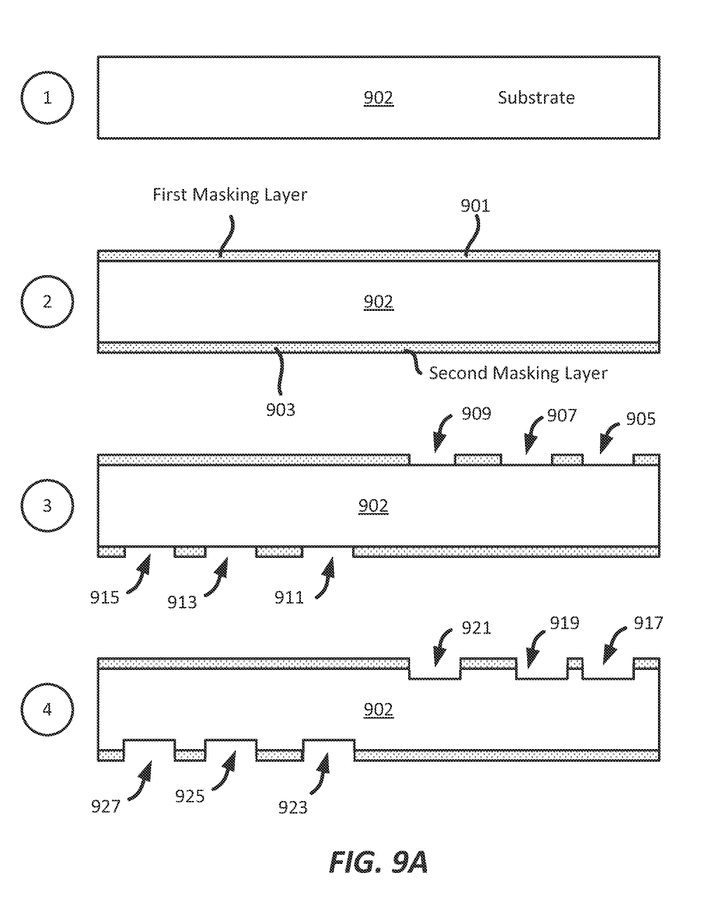

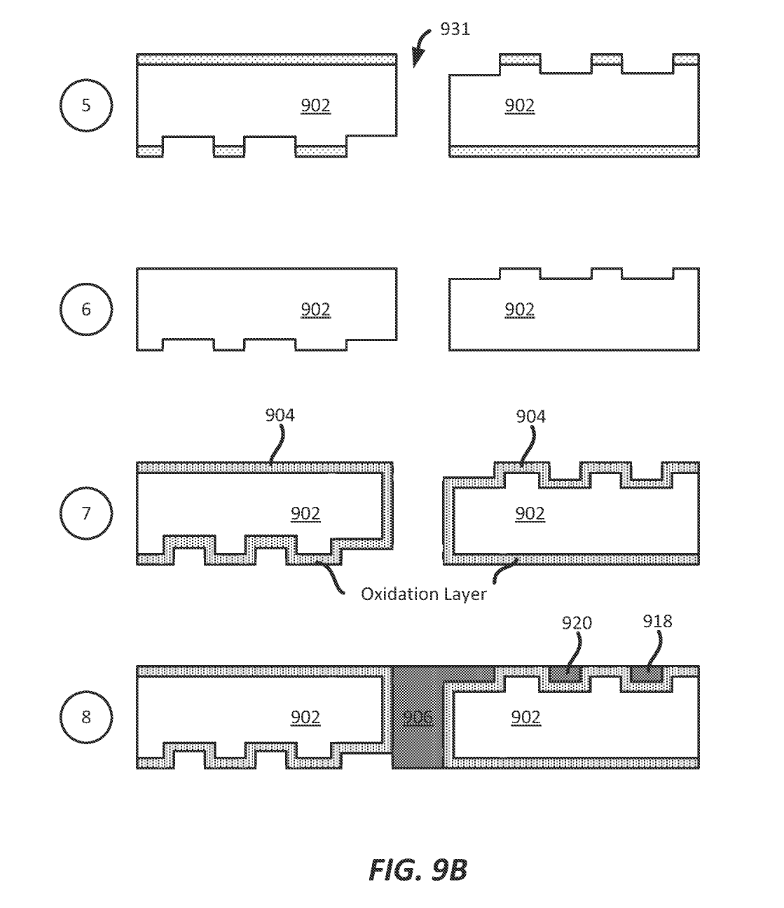

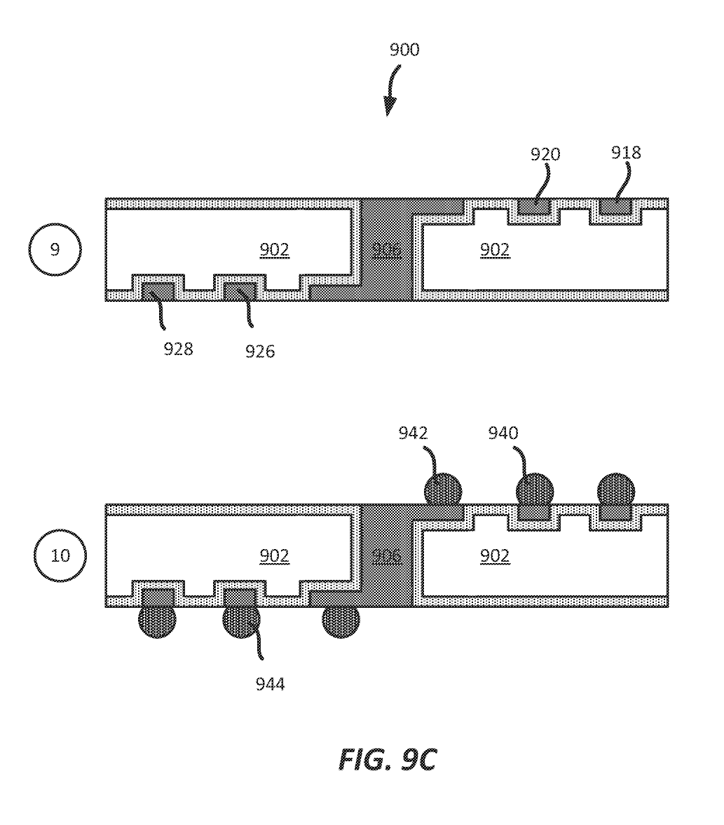

FIG. 9A-9C illustrate an exemplary sequence of a process for providing/manufacturing the interposer of FIG. 8. As shown in FIG. 9A, at stage 1, a substrate 902 is provided. In some implementations, the substrate 902 is a silicon substrate. The silicon substrate may have a thickness between 30-300 microns (μm) in some implementations. In some implementations, the substrate 902 is a wafer substrate.

At stage 2, a first masking layer 901 and a second masking layer 903 are provided on the substrate 902. Specifically, the first masking layer 901 is provided on a first surface (e.g., top surface) of the substrate 902 and the second masking layer 903 is provided on a second surface (e.g., bottom surface) of the substrate 902. Different implementations may provide the masking layers differently. In some implementations, the masking layers (e.g., hard mask) may be provided by using plasma-enhance chemical vapor deposition (PECVD) or providing a thermal oxide.

At stage 3, multiple mask cavities (e.g., mask cavities 905, 907, 909, 911, 913, 915) are created in the masking layers 901 and 903. Different implementations may use different techniques or processes for creating the mask cavities. In some implementations, the cavities are created by using a laser to drill in the masking layers 901 and 903. In some implementations, some removal of the silicon (e.g., substrate) below or above the cavities/openings of the masking layers may occur In some implementations, lithography and etching processes are use to create the mask cavities in the masking layers 901 and 903. In some implementations, cavities (e.g., substrate cavities) may also be created in the substrate 902 during the creation of the mask cavities.

At stage 4, substrate cavities (e.g., substrate cavities 917, 919, 921, 923, 925, 927) are selectively etched in the substrate 902. The location of these substrate cavities are based on the location of the corresponding mask cavities in some implementations. Different processes may be used to selectively etch the substrate 902 to create the substrate cavities. For example, a chemical process may be used to selectively etch the substrate 902 (e.g., using tramethylammonium hydroxide (TMAH) and/or potassium hydroxide (KOH)). The cavities/opening may have undercut beneath the hardmask (e.g., masking layer).

At stage 5 of FIG. 9B, a hole 931 that traverses the substrate 902 is provided/created. In some implementations, the hole 931 will become a via in the substrate 902. In some implementations, the hole 931 is created by using a laser. However, different implementations may the provide/create the hole 931 differently.

At stage 6, the masking layers 901 and 903 are removed from the substrate 902. In some implementations, the removal of the masking layers 901 and/or 903 is optional. Thus, in some implementations, stage 6 may be skipped. That is, in some implementations, one or more portions of the masking layers 901 and/or 903 may be left on the substrate. This may be the case when the masking layers 901 and/or 903 are a thermal oxide. In some implementations, the remaining masking layer may act/be configured to provide electrical insulation from the substrate.

At stage 7, an oxidation layer 904 is provided on the substrate 902. In some implementations, an oxidation layer 904 it provided on an exposed surface of the substrate 902 (e.g. all the exposed surface of the substrate 902). Different implementations may provide the oxidation layer 904 differently. In some implementations, the oxidation layer 904 is provided by exposing the substrate 902 to an oxidizing material (e.g., air, water, chemical), which forms the oxidation layer 904 (e.g., silicon oxide) on the surface of the substrate 902. In some implementations, the substrate 902 may be exposed to heat in oxidation environment (e.g., in a furnace) to form the oxidation layer 904 (e.g., thermal oxide). In the instance that the masking layers 901 and/or 903 are not removed (at stage 6), in some implementations, an oxidation layer is not formed above any remaining masking layer. In some implementations, the masking layer may act/be configured to provide electrical insulation from the substrate. In some implementations, the masking layer (e.g., masking layers 901, 903) is a thermal oxide and thus may be indistinguishable from oxidation layer 904. Thus, in some implementations, the oxidation layer 904 may include any remaining masking layer 901 and/or 903 on the substrate 902.

At stage 8, a metal layer is provided in some of the cavities and holes provided in the substrate. Different implementations may provide the metal layers differently. In some implementations, a screen printing process is used to provide the metal layers in the cavities and holes of the substrate. For example, a fill conductive paste (e.g., metal material) is provided in the cavities 917, 919, 921 and hole 931 using a screen printing tool. In some implementations, the cavities 917 and 919 which are filled with the conductive past form interconnects 918 and 920, while the cavity 921 and hole 931, which are filled with the conductive past form a partial via 906.

At stage 9, another metal layer is provided in some of the cavities and holes in the substrate. Different implementations may provide the metal layers differently. In some implementations, a screen printing process is used to provide the metal layers in the cavities and holes of the substrate. For example, a fill conductive paste is provided in the cavities 923, 925, and 927 using a screen printing tool. Although not shown, the substrate 900 may be flipped in order to provide the conductive paste. In some implementations, the cavities 925 and 927 which are filled with the conductive paste, form interconnects 926 and 928, while the cavity 923, which is filled with the conductive paste, forms the complete via 906. Once the metal layers (e.g., conductive paste) are provided, the interposer 900 is manufactured and complete in some implementations.

Since the conductive paste fills the cavities/trenchs in the substrate (e.g., silicon) and forms the interconnect/trace, the shape of the interconnect/trace shape will be defined by the cavity/trench. As a result, the minimum pitch (e.g., width plus space, center to center distance between two neighboring interconnects/traces) can be much lower than typical raised screen printing traces. For example, the minimum pitch between two raised traces using a screen printing process is 100 microns (μm). In contrast, the minimum pitch between embedded interconnects/traces may be 30 microns (μm) or less. In some implementations, the minimum pitch between embedded interconnects/traces can be as low as 10 microns (μm).

Another way to look at this advantage is that the spacing between two neighboring embedded interconnects/traces is lower than the spacing between two neighboring raised interconnects/traces. In addition, embedded interconnects/traces have better adhesion to the interposer (e.g., substrate and/or oxidation layer) than a raised trace and/or a trace that is completely on the surface of the interposer. This allows for more reliable, smaller interposers and/or interposers with higher density/concentration of interconnects/traces.

At stage 10, solder balls are provided to the interposer 900. These solder balls 940-944 may be coupled to the interconnects and vias of the interposer 900. Once the solder balls 940-944 are provided on the interposer 900, the interposer 900 may be coupled to a printed circuit board and/or die.

As mentioned above, the oxidation layer 904 provides an insulation layer that prevents electrical signals from traversing through the substrate 902. For example, the oxidation layer 904 may be configured to provide electrical insulation between the via 906 and the substrate 902. In some implementations, the oxidation layer 904 may be configured to provide electrical insulation between the interconnect/trace (e.g., interconnects 908, 910) and the substrate 902.

In some implementations, the interposer 900 may be configured to be positioned between a printed circuit board (PCB) and at least one die. For example, the novel interposer 900 may replace the interposer 106 of FIG. 1 in some implementations. In some implementations, the substrate that is used to provide/manufacture the interposer 900 is a substrate from a wafer (e.g., wafer 600).

Having described a sequence for providing a novel interposer that includes an oxidation layer, a method for providing/manufacturing an interposer that includes an oxidation layer will now be described.

Exemplary Interposer with Multiple Insulative Layers

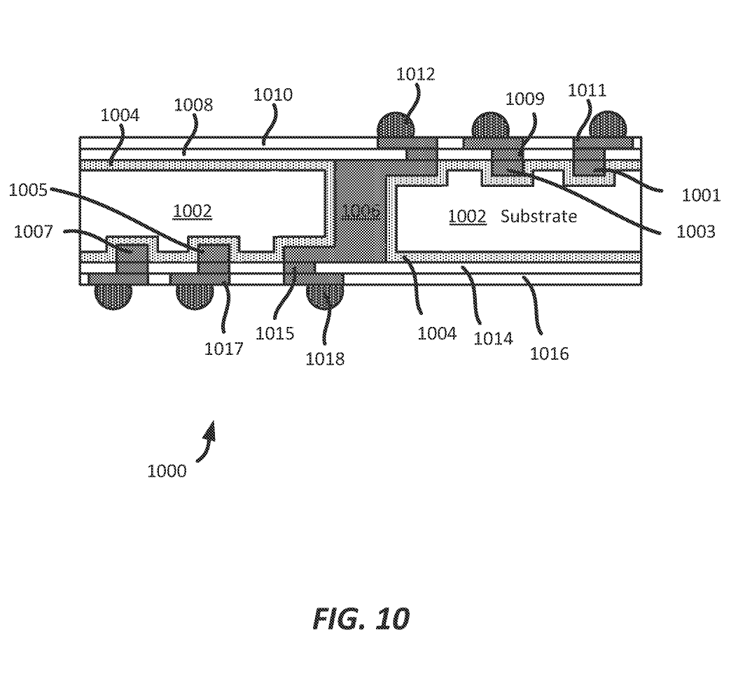

In some implementations, an interposer may includes additional insulative layers. FIG. 10 illustrates an example of an interposer that includes a via, interconnects and multiple layers. FIG. 10 is similar to FIG. 8, except that in FIG. 10, the interposer includes additional insulative layers and solder balls.

Specifically, FIG. 10 illustrates an interposer 1000 that includes a substrate 1002, an oxidation layer 1004, a first metal layer 1006, a first interconnect 1001, a second interconnect 1003, a third interconnect 1005 and a fourth interconnect 1007. The substrate 1002 may be a silicon substrate in some implementations. The oxidation layer 1004 is a layer that is formed on an exposed surface of the substrate 1002. In some implementations, the oxidation layer 1004 may provide electrical insulation/isolation in the interposer 1000 (e.g., prevents electrical signal from traversing through substrate). The first metal layer 1006 defines a via in the interposer 1000.

The interposer 1000 also includes a first insulative layer 1008, a second insulative layer 1010, a first distribution layer 1009, a second distribution layer 1011 and a set of solder balls 1012. The first insulative layer 1008 and the second insulative 1010 may be a dielectric layer or polymer. The first distribution layer 1009 and the second distribution layer 1011 may be a metal layer that is coupled to the via and the interconnect on a first side/surface (e.g., top surface) of the interposer 1000. In some implementations, the first distribution layer 1008 and the second distribution layer 1011 provide an electrical path between the solder balls 1012 and the first metal layer (e.g., via), the first interconnect 1001 and the second interconnect 1003.

The interposer 1000 also includes a third insulative layer 1014, a second insulative layer 1016, a first distribution layer 1015, a second distribution layer 1017 and a set of solder balls 1018. The third insulative layer 1014 and the fourth insulative 1016 may be a dielectric layer. The third distribution layer 1015 and the fourth distribution layer 1017 may be a metal layer that is coupled to the via and the interconnect on a second side/surface (e.g., bottom surface) of the interposer 1000. In some implementations, the third distribution layer 1015 and the fourth distribution layer 1017 provide an electrical path between the solder balls 1018 and the first metal layer (e.g., via), the third interconnect 1005 and the fourth interconnect 1007.

Exemplary Method for Providing/Manufacturing an Interposer that Includes an Oxidation Layer

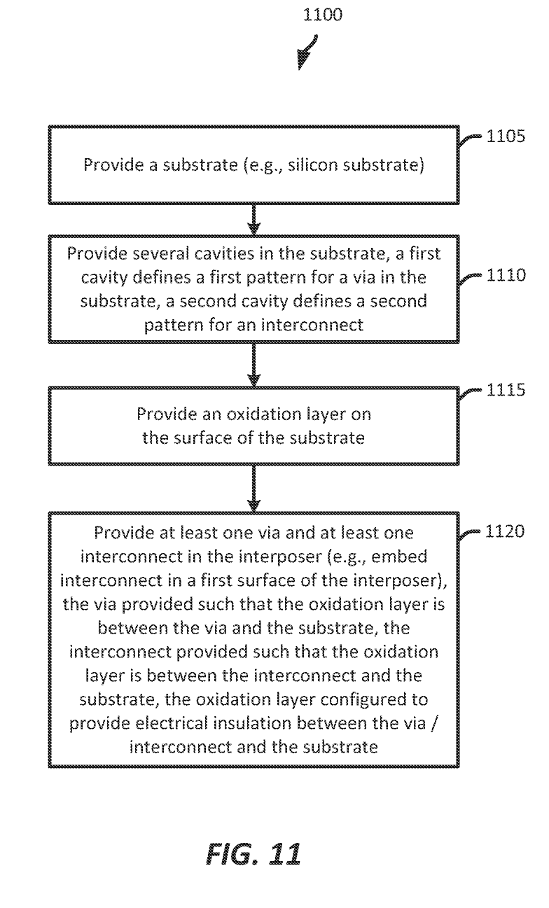

FIG. 11 illustrates an exemplary method for providing/manufacturing an interposer that includes an oxidation layer. In some implementations, the method of FIG. 11 may be used to provide/manufacture the interposers of FIGS. 8 and/or 9A-9C, as well as other interposers described in the present disclosure. As shown in FIG. 11, the method provides (at 1105) a substrate. In some implementations, the substrate is a silicon substrate. The silicon substrate may have a thickness between 30-300 microns (μm) in some implementations. The substrate may be a singular piece of substrate that is cut from a wafer (e.g., wafer 600) in some implementations. In some implementations, providing (at 1105) the substrate may include providing a wafer (e.g., wafer 600).

The method provides (at 1110) multiple cavities in the substrate and/or wafer. A first cavity defines a first pattern for a via in the substrate. A second cavity defines a second pattern for an interconnect/trace on the substrate. Different implementations may provide the cavity by using different techniques and processes.

In some implementations, providing (at 1110) a cavity that defines an interconnect/trace on a substrate includes providing one or more masking layers, creating cavities in the masking layers and the substrate and removing the one more masking layers.

Specifically, in some implementations, providing (at 1110) a cavity that defines an interconnect/trace on a substrate includes providing (at 1110) a first masking layer (e.g., first patterned mask layer) on a first surface (e.g., top surface) of the substrate and providing (at 1110) a second masking layer (e.g., second patterned mask layer) on a second surface (e.g., bottom surface) of the substrate. Different implementations may provide the masking layers differently. In some implementations, the masking layers (e.g., hard mask) may be provided by using plasma-enhance chemical vapor deposition (PECVD) or providing a thermal oxide.

In some implementations, providing (at 1110) a cavity that defines an interconnect/trace also includes providing/creating multiple mask cavities (e.g., mask cavities 905, 907, 909, 911) in the masking layers. Different implementations may use different techniques or processes for creating the mask cavities. In some implementations, the mask cavities are created by using a laser to drill in the masking layers. In some implementations, lithography and etching processes are use to create the mask cavities in the masking layers.

In some implementations, providing (at 1110) a cavity that defines an interconnect/trace also includes selectively etching substrate cavities (e.g., substrate cavities 917, 919) in the substrate. The location of these substrate cavities are based on the location of the corresponding mask cavities in some implementations. Different processes may be used to selectively etch the substrate to create the substrate cavities. For example, a chemical process may be used to selectively etch the substrate (e.g., using tramethylammonium hydroxide (TMAH) and/or potassium hydroxide (KOH)).

In some implementations, providing (at 1110) a cavity that defines an interconnect/trace also includes removing the masking layers from the substrate.

In some implementations, providing (at 1110) the cavity that defines a via includes using a laser to drill the at least one cavity in the substrate (e.g., substrate 902). In some implementations, providing (at 1110) the at least one cavity includes pattern etching (e.g., lithography, chemical process, dry etching, wet etching). In the instance that multiple cavities are provides in the substrate, the cavities may be provided/created sequentially or concurrently in the substrate and/or wafer. The providing of the cavity that defines a via may performed before a masking layer is removed in some implementations. In some implementations, the providing of the cavity that defines the via is performed after a masking layer is removed.

The method then provides (at 1115) an oxidation layer on the substrate and/or wafer. In some implementations, providing (at 1115) the oxidation layer includes providing an oxidation layer on an exposed surface of the substrate. Different implementations may provide the oxidation layer differently. In some implementations, the oxidation layer is provided by exposing the substrate to an oxidizing material (e.g., air, water, chemical), which forms the oxidation layer (e.g., silicon oxide) on the surface of the substrate and/or wafer. In some implementations, the substrate may be exposed to heat under an oxidation environment (e.g., in a furnace) to form the oxidation layer (e.g., thermal oxide). In some implementations, the oxidation layer is provided on a first surface (e.g., top surface) of the substrate during a first exposure of the substrate to heat under an oxidation environment (e.g., in a furnace) and then the oxidation layer is provided on a second surface (e.g., bottom surface) of the substrate during a second exposure of the substrate to heat under an oxidation environment (e.g., in furnace). In some implementations, the oxidation layer is provided on the entire surface of the substrate during a single exposure of the substrate to heat under an oxidation environment (e.g., in a furnace). The oxidation layer may be a liner in some implementations.

The method then provides (at 1120) at least one via in the substrate and at least one interconnect on the interposer (e.g., substrate). In some implementations, providing (at 1120) the at least one via includes filling one or more the cavities with a metal material (e.g., copper) to define one or more vias in the substrate. The one or more vias are provided on the substrate such that the oxidation layer is between the via and the substrate. The oxidation layer is configured to provide electrical insulation between the via and the substrate. Different implementations may provide the one or more vias differently.

In some implementations, providing (at 1120) the at least one interconnect includes filling one or more the cavities with a metal material (e.g., copper) to define one or more interconnects on the interposer (e.g., substrate and/or oxidation layer). The one or more interconnects are provided on the interposer (e.g., substrate) such that the oxidation layer is between the interconnects and the substrate. The oxidation layer is configured to provide electrical insulation between the interconnects and the substrate. Different implementations may provide the one or more interconnects differently. In some implementations, providing at least one interconnect includes providing at least one embedded interconnect on a surface of an interposer, where at least one area of the embedded interconnect is exposed.

In some implementations, providing (at 1120) one or more vias/interconnect includes providing a masking layer (e.g., patterned mask layer) on the interposer. Specifically, a masking layer is provided on the oxidation layer that is on the substrate. Different implementations may use different materials and methods for providing for the masking layer. For example, the masking layer may be an electrodeless seed layer.

In some implementations, providing (at 1120) one or more vias/interconnect also includes selectively etching one or more portions of the masking layer. Different implementations may use different methods for selectively etch the masking layer. In some implementations, lithography may be used to selectively etch the masking layer, which forms patterns/cavities (e.g., cavities 303, 305) that define the outline of one or more vias/interconnects or portions of one or more vias/interconnects.

In some implementations, providing (at 1120) one or more vias/interconnects also includes providing a material (e.g., metal material, conductive paste) in the patterns/cavities. The material defines the one or more vias/interconnects in the substrate of the interposer. Different implementations may provide the material differently. In some implementations, the material (e.g., metal layer) may be deposited, plated and/or pasted in the patterns/cavities.

In some implementations, providing (at 1120) one or more vias/interconnects also includes removing the masking layer, leaving an interposer with an oxidation layer and one or more vias/interconnects. In some implementations, removing the masking layer includes removing an electrodeless seed layer.

In some implementations, when the substrate that is provided (at 1105) is a wafer (e.g., wafer 600), the method may cut (e.g., after 1120) the wafer into singular pieces of interposers (e.g., interposer 602) using known cutting/dicing techniques and processes.

### Exemplary Electronic Devices

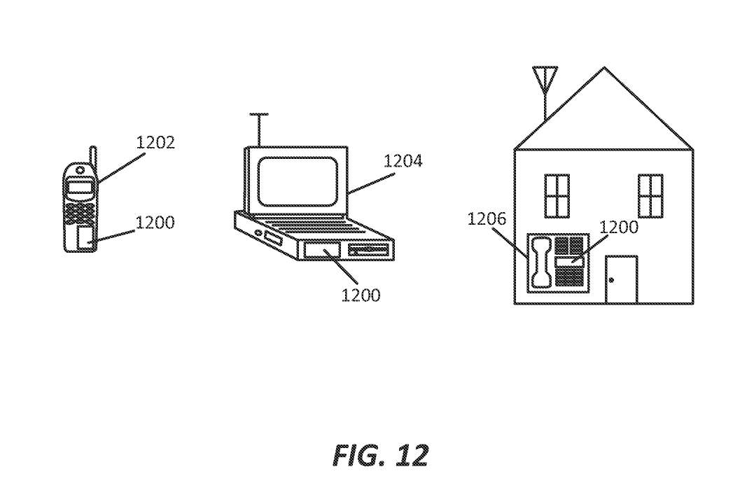

FIG. 12 illustrates various electronic devices that may be integrated with any of the aforementioned integrated circuit, die or package. For example, a mobile telephone 1202, a laptop computer 1204, and a fixed location terminal 1206 may include an integrated circuit (IC) 1200 as described herein. The IC 1200 may be, for example, any of the integrated circuits, dice or packages described herein. The devices 1202, 1204, 1206 illustrated in FIG. 12 are merely exemplary. Other electronic devices may also feature the IC 1200 including, but not limited to, mobile devices, hand-held personal communication systems (PCS) units, portable data units such as personal digital assistants, GPS enabled devices, navigation devices, set top boxes, music players, video players, entertainment units, fixed location data units such as meter reading equipment, communications devices, smartphones, tablet computers or any other device that stores or retrieves data or computer instructions, or any combination thereof

One or more of the components, steps, features, and/or functions illustrated in FIGS. 2, 3A-3B, 4A-4C, 5, 6, 7, 8, 9A-9C, 10, 11 and/or 12 may be rearranged and/or combined into a single component, step, feature or function or embodied in several components, steps, or functions. Additional elements, components, steps, and/or functions may also be added without departing from the invention.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other.

Also, it is noted that the embodiments may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

The various features of the invention described herein can be implemented in different systems without departing from the invention. It should be noted that the foregoing aspects of the disclosure are merely examples and are not to be construed as limiting the invention. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. An interposer comprising:
a substrate;
a via in the substrate, the via comprising a metal material;
a first interconnect embedded in a first surface of the interposer, wherein a first area of the first interconnect is exposed; and
an oxidation layer located between the via and the substrate, the oxidation layer further located between the interconnect and the substrate.

2. The interposer of claim 1, wherein the substrate is a silicon substrate.

3. The interposer of claim 1, wherein the oxidation layer is a thermal oxide formed by exposing the substrate to heat.

4. The interposer of claim 1, wherein the oxidation layer covers the entire surface of the substrate.

5. The interposer of claim 1 further comprising an insulation layer.

6. The interposer of claim 5, wherein the insulation layer is a polymer layer.

7. The interposer of claim 5, wherein the oxidation layer covers a second surface portion of the substrate.

8. The interposer of claim 1, further comprising a second interconnect on a second surface of the interposer, wherein the oxidation layer is further between the second interconnect and the substrate.

9. The interposer of claim 1, wherein the interposer is configured to be positioned between a printed circuit board (PCB) and at least one die.

10. The interposer of claim 1, wherein the oxidation layer is configured to provide electrical insulation between the via and the substrate.

11. The interposer of claim 1, wherein the interposer is incorporated into at least one of a music player, a video player, an entertainment unit, a navigation device, a communications device, a mobile device, a mobile phone, a smartphone, a personal digital assistant, a fixed location terminal, a tablet computer, and/or a laptop computer.

12. An apparatus comprising:
a substrate;
a via in the substrate, the via comprising a metal material;
a first interconnect embedded in a first surface of the apparatus, wherein a first area of the first interconnect is exposed; and
a means for electrical insulation between the via and the substrate, the means for electrical insulation further between the first interconnect and the substrate.

13. The apparatus of claim 12, wherein the substrate is a silicon substrate.

14. The apparatus of claim 12, wherein the means for electrical insulation comprises an oxidation layer that is a thermal oxide formed by exposing the substrate to heat.

15. The apparatus of claim 12, wherein the means for electrical insulation comprises an oxidation layer that covers the entire surface of the substrate.

16. The apparatus of claim 12, wherein the means for electrical insulation comprises an oxidation layer and an insulation layer.

17. The apparatus of claim 16, wherein the insulation layer is a polymer layer.

18. The apparatus of claim 16, wherein the oxidation layer covers a second surface portion of the substrate.

19. The apparatus of claim 12, further comprising a second interconnect on a second surface of the apparatus, wherein the oxidation layer is further between the second interconnect and the substrate.

20. The apparatus of claim 12, wherein the apparatus is an interposer that is configured to be positioned between a printed circuit board (PCB) and at least one die.

21. The apparatus of claim 12, wherein the apparatus is incorporated into at least one of a music player, a video player, an entertainment unit, a navigation device, a communications device, a mobile device, a mobile phone, a smartphone, a personal digital assistant, a fixed location terminal, a tablet computer, and/or a laptop computer.

22. A method for providing an interposer, comprising:
providing a substrate;
providing an oxidation layer on the substrate;
providing a via in the substrate, the via comprising a metal material, the via provided in the substrate such that the oxidation layer is between the via and the substrate; and
providing a first interconnect in the substrate such that the first interconnect is embedded in a first surface of the interposer, and the oxidation layer is between the first interconnect and the substrate, wherein a first area of the first interconnect is exposed.

23. The method of claim 22, wherein the substrate is a silicon substrate.

24. The method of claim 22, wherein the oxidation layer is a thermal oxide formed by exposing the substrate to heat.

25. The method of claim 22, wherein the oxidation layer covers the entire surface of the substrate.

26. The method of claim 22 further comprising providing an insulation layer.

27. The method of claim 26, wherein the insulation layer is a polymer layer.

28. The method of claim 26, wherein providing the insulation layer comprises providing the insulation layer on the oxidation layer.

29. The method of claim 22, further comprising providing a second interconnect in the substrate such that the second interconnect is embedded in a second surface of the substrate and the oxidation layer is between the second interconnect and the substrate.

30. The method of claim 22, wherein the interposer is configured to be positioned between a printed circuit board (PCB) and at least one die.

31. The method of claim 22, wherein the oxidation layer is configured to provide electrical insulation between the via and the substrate.

32. The method of claim 22, wherein the interposer is incorporated into at least one of a music player, a video player, an entertainment unit, a navigation device, a communications device, a mobile device, a mobile phone, a smartphone, a personal digital assistant, a fixed location terminal, a tablet computer, and/or a laptop computer.
